(19) United States
(12) Patent Application Publication
(10) Pub. No.: US 2025/0203888 A1
(43) Pub. Date: Jun. 19, 2025

(54) MULTILAYER METAL-INSULATOR-METAL CAPACITORS FOR INCREASED CAPACITANCE DENSITY

(71) Applicant: Samsung Electronics Co., Ltd., Suwon-si (KR)

(72) Inventor: Sunil Kumar SINGH, Round Rock, TX (US)

(21) Appl. No.: 18/590,905

(22) Filed: Feb. 28, 2024

Related U.S. Application Data
(60) Provisional application No. 63/612,358, filed on Dec. 19, 2023.

(51) Int. Cl. H01L 21/02; H01L 21/308; H01L 21/3213

(52) U.S. Cl. CPC H10D 1/68; H01L 21/02068; H01L 21/308; H01L 21/32139

(57) ABSTRACT

Provided are multilayer metal-insulator-metal (MIM) capacitors and methods for forming such capacitors. A MIM capacitor includes a first metal layer of a first metal type on a first substrate layer, a semiconductor layer on the first metal layer, a second metal layer of the first metal type on the semiconductor layer, and a first photoresist and a second photoresist applied to the second metal layer, where the first metal layer, the semiconductor layer, and the second metal layer are formed via thin-film deposition, and rows of the first metal layer, the semiconductor layer, and the second metal layer are formed based on etching exposed portions of the first metal layer, the semiconductor layer, and the second metal layer between the first photoresist and the second photoresist.

### CROSS-REFERENCE TO RELATED APPLICATIONS

This application claims the benefit of U.S. Provisional Patent Application Ser. No. 63/612,358, filed Dec. 19, 2023, which is incorporated by reference herein for all purposes.

### TECHNICAL FIELD

The subject matter disclosed here relates integrated circuit (IC) fabrication. In particular, the subject matter relates to fabrication (e.g., back end of line fabrication) of multilayer metal-insulator-metal capacitors for increased capacitance density.

### BACKGROUND

The present background section is intended to provide context only, and the disclosure of any concept in this section does not constitute an admission that said concept is prior art.

Capacitors are a passive electrical component that store electrical energy. Capacitors can be formed with two electrical conductors that are separated by a distance and have equal and opposite charges. The space between the conductors can be filled with a vacuum or an insulating material called a dielectric. Metal-insulator-metal (MIM) capacitors are formed by using metal-insulator-metal layers. The technique creates capacitors with high capacitance density, low leakage current, and low parasitic resistance.

The above information disclosed in this Background section is only for enhancement of understanding of the background of the disclosure and therefore it may contain information that does not constitute prior art.

### SUMMARY

In various embodiments, the techniques described herein include systems, methods, and apparatuses for multilayer metal-insulator-metal capacitors for increased capacitance density.

In some aspects, the techniques described herein relate to a method of fabricating a semiconductor device, including: forming a first metal layer of a first metal type on a first substrate layer; forming a semiconductor layer on the first metal layer; forming a second metal layer of the first metal type on the semiconductor layer; applying a first photoresist and a second photoresist to the second metal layer, wherein the first photoresist spans a first portion of the second metal layer and the second photoresist spans a second portion of the second metal layer different from the first portion; and forming rows of the first metal layer, the semiconductor layer, and the second metal layer based on etching exposed portions of the first metal layer, the semiconductor layer, and the second metal layer between the first photoresist and the second photoresist.

In some aspects, the techniques described herein relate to a method, wherein the rows include a metal-insulator-metal (MIM) capacitor area of the semiconductor device.

In some aspects, the techniques described herein relate to a method, wherein: the semiconductor layer includes amorphous silicon, and the first metal layer, the semiconductor layer, and the second metal layer are formed via thin-film deposition.

In some aspects, the techniques described herein relate to a method, further including depositing a second substrate layer over the rows, wherein the second substrate layer encapsulates the rows.

In some aspects, the techniques described herein relate to a method, further including forming a planar surface over the second substrate layer based on chemical mechanical polishing.

In some aspects, the techniques described herein relate to a method, further including applying a third photoresist and a fourth photoresist on the second substrate layer.

In some aspects, the techniques described herein relate to a method, further including exposing the rows based on etching the third photoresist, the fourth photoresist, portions of the second substrate layer between the rows, and portions of the first substrate layer between the rows.

In some aspects, the techniques described herein relate to a method, wherein the third photoresist is applied adjacent to a first edge of the second substrate layer and the fourth photoresist is applied adjacent a second edge of the second substrate layer.

In some aspects, the techniques described herein relate to a method, wherein a first sidewall of the second substrate layer remains based on the third photoresist and a second sidewall of the second substrate layer remains based on the fourth photoresist, the first sidewall including the first edge and the second sidewall including the second edge of the second substrate layer.

In some aspects, the techniques described herein relate to a method, further including removing the semiconductor layer between the first metal layer and the second metal layer based on applying a wet clean solution to the rows.

In some aspects, the techniques described herein relate to a method, wherein the wet clean solution forms a cavity, the second substrate layer forming sidewalls of the cavity and the rows being within the cavity.

In some aspects, the techniques described herein relate to a method, further including depositing a dielectric layer over the rows and between the rows, over a surface of the first substrate layer between the rows, and over a surface of the second substrate layer.

In some aspects, the techniques described herein relate to a method, wherein the dielectric layer is deposited based on atomic layer deposition.

In some aspects, the techniques described herein relate to a method, further including depositing a second metal type over and between the rows, wherein the second metal type covers the rows and the dielectric layer and fills in space between the rows.

In some aspects, the techniques described herein relate to a method, further including forming a planar surface over the second metal type based on chemical mechanical polishing.

In some aspects, the techniques described herein relate to a semiconductor device, including: a first metal layer of a first metal type formed on a first substrate layer; a semiconductor layer formed on the first metal layer via film stack deposition; a second metal layer of the first metal type formed on the semiconductor layer; and a first photoresist and a second photoresist applied to the second metal layer, wherein: the first metal layer, the semiconductor layer, and the second metal layer are formed via thin-film deposition, the first photoresist spans a first portion of the second metal layer and the second photoresist spans a second portion of the second metal layer different from the first portion, and rows of the first metal layer, the semiconductor layer, and the second metal layer are formed based on an etching of exposed portions of the first metal layer, the semiconductor layer, and the second metal layer between the first photoresist and the second photoresist.

In some aspects, the techniques described herein relate to a semiconductor device, wherein: the rows include a metal-insulator-metal (MIM) capacitor area of the semiconductor device, and the semiconductor layer includes amorphous silicon.

In some aspects, the techniques described herein relate to a semiconductor device, further including: a second substrate layer deposited over the rows, wherein the second substrate layer encapsulates the rows; and a planar surface formed over the second substrate layer based on chemical mechanical polishing.

In some aspects, the techniques described herein relate to a semiconductor device, further including a third photoresist and a fourth photoresist applied on the second substrate layer, wherein the third photoresist is applied adjacent to a first edge of the second substrate layer and the fourth photoresist is applied adjacent a second edge of the second substrate layer.

In some aspects, the techniques described herein relate to a semiconductor device, further including exposing the rows based on etching the third photoresist, the fourth photoresist, portions of the second substrate layer between the rows, and portions of the first substrate layer between the rows, wherein a first sidewall of the second substrate layer remains based on the third photoresist and a second sidewall of the second substrate layer remains the fourth photoresist, the first sidewall including the first edge and the second sidewall including the second edge of the second substrate layer.

A computer-readable medium is disclosed. The computer-readable medium can store instructions that, when executed by a computer, cause the computer to perform substantially the same or similar operations as described herein are further disclosed. Similarly, non-transitory computer-readable media, devices, and systems for performing substantially the same or similar operations as described herein are further disclosed.

The techniques described herein include multiple advantages and benefits, and remedy the problems with some MIM devices. For example, the MIM structures described herein provide an increased capacitance density with a relatively small space (e.g., relatively small MIM area) compared to other MIM structures. Also, the MIM structures described herein provide lower series resistance. Additionally, the described techniques provide methods and processes for forming multilayer MIM capacitors with increased capacitance density and lower series resistance compared to other methods and processes. Furthermore, the proposed process offers additional advantage of saving a mask layer (e.g., using at least one less mask layer than other processes), which results in a significant reduction to the cost of manufacturing.

### BRIEF DESCRIPTION OF THE DRAWINGS

The above-mentioned aspects and other aspects of the present techniques will be better understood when the present application is read in view of the following figures in which like numbers indicate similar or identical elements. Further, the drawings provided herein are for purpose of illustrating certain embodiments only; other embodiments, which may not be explicitly illustrated, are not excluded from the scope of this disclosure.

These and other features and advantages of the present disclosure will be appreciated and understood with reference to the specification, claims, and appended drawings wherein:

FIG. 1 illustrates a cross-sectional view illustrating an example of a semiconductor device in accordance with one or more implementations as described herein.

FIG. 2 illustrates a cross-sectional view illustrating an example of a semiconductor device in accordance with one or more implementations as described herein.

FIG. 3 illustrates a cross-sectional view illustrating an example of a semiconductor device in accordance with one or more implementations as described herein.

FIG. 4 illustrates a cross-sectional view illustrating an example of a semiconductor device in accordance with one or more implementations as described herein.

FIG. 5 illustrates a three-dimensional top-down view illustrating an example of a semiconductor device in accordance with one or more implementations as described herein.

FIG. 6 illustrates a cross-sectional view illustrating an example of a semiconductor device in accordance with one or more implementations as described herein.

FIG. 7 illustrates a cross-sectional view illustrating an example of a semiconductor device in accordance with one or more implementations as described herein.

FIG. 8 illustrates a cross-sectional view illustrating an example of a semiconductor device in accordance with one or more implementations as described herein.

FIG. 9 depicts a flow diagram illustrating an example method associated with the disclosed systems, in accordance with example implementations described herein.

FIG. 10 depicts a flow diagram illustrating an example method associated with the disclosed systems, in accordance with example implementations described herein.

While the present techniques are susceptible to various modifications and alternative forms, specific embodiments thereof are shown by way of example in the drawings and will herein be described. The drawings may not be to scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims.

### DETAILED DESCRIPTION OF VARIOUS EMBODIMENTS

The details of one or more embodiments of the subject matter described herein are set forth in the accompanying drawings and the description below. Other features, aspects, and advantages of the subject matter will become apparent from the description, the drawings, and the claims.

The present techniques relate to semiconductor devices with capacitors of a metal/insulator/metal (MIM) structure (MIM capacitors) and methods for fabricating the same. More particularly, the present techniques relate to semiconductor devices with multilayer MIM capacitors that provide increased capacitance density and methods for fabricating the same.

Various embodiments of the present disclosure now will be described more fully hereinafter with reference to the accompanying drawings, in which some, but not all embodiments are shown. Indeed, the disclosure may be embodied in many different forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Like numbers refer to like elements throughout. Arrows in each of the figures depict bi-directional data flow and/or bi-directional data flow capabilities. The terms “path,” “pathway” and “route” are used interchangeably herein. Embodiments of the present disclosure may be implemented in various ways, including as computer program products that comprise articles of manufacture.

As should be appreciated, various embodiments of the present disclosure may be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may take the form of an entirely hardware embodiment, an entirely computer program product embodiment, and/or an embodiment that comprises a combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (for example the executable instructions, instructions for execution, program code, and/or the like) on a computer-readable storage medium for execution. For example, retrieval, loading, and execution of code may be performed sequentially, such that one instruction is retrieved, loaded, and executed at a time. In some examples, retrieval, loading, and/or execution may be performed in parallel, such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

The following description is presented to enable one of ordinary skill in the art to make and use the subject matter disclosed herein and to incorporate it in the context of particular applications. While the following is directed to specific examples, other and further examples may be devised without departing from the basic scope thereof.

Various modifications, as well as a variety of uses in different applications, will be readily apparent to those skilled in the art, and the general principles defined herein may be applied to a wide range of embodiments. Thus, the subject matter disclosed herein is not intended to be limited to the embodiments presented, but is to be accorded the widest scope consistent with the principles and novel features disclosed herein.

In the description provided, numerous specific details are set forth in order to provide a more thorough understanding of the subject matter disclosed herein. It will, however, be apparent to one skilled in the art that the subject matter disclosed herein may be practiced without necessarily being limited to these specific details. In other instances, well-known structures and devices are shown in block diagram form, rather than in detail, in order to avoid obscuring the subject matter disclosed herein.

All the features disclosed in this specification (e.g., any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Various features are described herein with reference to the figures. It should be noted that the figures are only intended to facilitate the description of the features. The various features described are not intended as an exhaustive description of the subject matter disclosed herein or as a limitation on the scope of the subject matter disclosed herein. Additionally, an illustrated example need not have all the aspects or advantages shown. An aspect or an advantage described in conjunction with a particular example is not necessarily limited to that example and can be practiced in any other examples even if not so illustrated, or if not so explicitly described.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

It is noted that, if used, the labels left, right, front, back, top, bottom, forward, reverse, clockwise and counterclockwise have been used for convenience purposes only and are not intended to imply any particular fixed direction. Instead, the labels are used to reflect relative locations and/or directions between various portions of an object.

Moreover, the terms “system,” “component,” “module,” “interface,” “model,” or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Unless explicitly stated otherwise, each numerical value and range may be interpreted as being approximate, as if the word “about” or “approximately” preceded the value of the value or range. Signals and corresponding nodes or ports might be referred to by the same name and are interchangeable for purposes here.

While embodiments may have been described with respect to circuit functions, the embodiments of the subject matter disclosed herein are not limited. Possible implementations may be embodied in a single integrated circuit, a multi-chip module, a single card, system-on-a-chip, or a multi-card circuit pack. As would be apparent to one skilled in the art, the various embodiments might also be implemented as part of a larger system. Such embodiments may be employed in conjunction with, for example, a digital signal processor, microcontroller, field-programmable gate array, application-specific integrated circuit, or general-purpose computer.

As would be apparent to one skilled in the art, various functions of circuit elements may also be implemented as processing blocks in a software program. Such software may be employed in, for example, a digital signal processor, microcontroller, or general-purpose computer. Such software may be embodied in the form of program code embodied in tangible media, such as magnetic recording media, optical recording media, solid-state memory, floppy diskettes, CD-ROMs, hard drives, or any other non-transitory machine-readable storage medium, that when the program code is loaded into and executed by a machine, such as a computer, the machine becomes an apparatus for practicing the subject matter disclosed herein. When implemented on a general-purpose processor, the program code segments combine with the processor to provide a unique device that operates analogously to specific logic circuits. Described embodiments may also be manifest in the form of a bit stream or other sequence of signal values electrically or optically transmitted through a medium, stored magnetic-field variations in a magnetic recording medium, etc., generated using a method and/or an apparatus as described herein.

Capacitors are used for energy storage, signal filtering, and high-frequency tuning applications. Capacitors are based on two metal plates separated by a dielectric material. A metal-insulator-metal (MIM) capacitor is a thin-film capacitor. MIM capacitors are parallel plate capacitors that can be made up of at least two metal films. MIM capacitors have a thin insulating dielectric layer between a capacitor top metal (CTM) layer and a capacitor bottom metal (CBM) layer. MIM layers can be made from aluminum, copper, aluminum-copper alloys, aluminum oxide, titanium, titanium nitride, tantalum, tantalum nitride, etc. MIM capacitors are used in integrated circuits and are a building block of electronic systems. MIM capacitors have low leakage current, low parasitic resistance, and a higher capacitance density compared to other types of capacitors, meaning they can store more charge in a smaller area.

Dielectrics are materials that don't allow current to flow. Dielectrics may be referred to as insulators. The dielectric constant k is a coefficient that measures a material's ability to store electrical energy. The dielectric constant (e.g., relative permittivity) is the ratio of a material's permittivity to the permittivity of free space. Low dielectric constant values may be used for high-frequency or power applications to minimize electric power loss. High dielectric constant values allow a capacitor to store more electrical energy than a capacitor with a low-dielectric material. When an electric field is applied to a material with a high dielectric constant, the electric charges within the material become polarized. This polarized state allows the material to store more electrical energy.

The front end of line (FEOL) is a portion (e.g., the first portion) of integrated circuit (IC) fabrication where individual components (transistors, capacitors, resistors, etc.) are patterned in the semiconductor. FEOL generally covers fabrication up to, but not including, the deposition of metal interconnect layers. The back end of line (BEOL) is a portion (e.g., the second portion) of IC fabrication where the individual devices (transistors, capacitors, resistors, etc.) get interconnected with wiring on the wafer, the metallization layer. Common metals are copper and aluminum. BEOL generally begins when the first layer of metal is deposited on the wafer. BEOL includes contacts, insulating layers (dielectrics), metal levels, and bonding sites for chip-to-package connections. After the last FEOL step, there is a wafer with isolated transistors (e.g., without any wires). In BEOL part of fabrication stage contacts (pads), interconnect wires, vias and dielectric structures are formed. Multiple metal layers can be added in the BEOL.

Deposition is a fabrication process that involves depositing thin films of materials (e.g., nanometers thickness) on a wafer. Deposition processes create layers of metal and dielectric (insulating) materials that are used to build semiconductor devices. Deposition technology is used in the manufacturing of computers, thin film transistors, semiconductors, etc. Stack deposition fabrication may be based on a physical vapor deposition cluster tool to deposit different metal and insulator layers.

Film stack deposition is a process that involves stacking films from bottom to top. The films may be annealed, and each film may be made from a different material. Film deposition involves depositing a thin metallic film coating onto a substrate. Thin film deposition involves processing above the substrate surface. Material is added to the substrate in the form of thin film layers. The layers can be either structural layers or act as spacers later to be removed. The deposition of thin films on a surface may be used for modifying the physical or chemical properties of the surface of the coated material. Thin film deposition can change optical, electrical, and/or thermal properties of affected materials. Thin film deposition processes may be based on one or any combination of evaporation, sputtering, ion beam deposition, pulsed laser deposition, chemical vapor deposition, atomic layer deposition, and the like. Atomic layer deposition (ALD) is a manufacturing technique that can be used in semiconductor fabrication. ALD is a vapor phase process that deposits thin films one atomic layer at a time. ALD can be used to deposit materials and films in precise places, such as metals on top of metals, or dielectrics on dielectrics, etc.

Thin-film metal deposition involves depositing a thin metallic film onto a surface, such as a substrate. Thin-film metal deposition is used in the manufacturing of semiconductors, optics, lasers, biosensors, and other specialized photolithography applications. Thin-film metals may include Gold (Au), Titanium (Ti), Silver (Ag), Aluminum (Al), Copper (Cu), Platinum (Pt), Nickel (Ni), Chromium (Cr), Tungsten (W), etc. Thin-film metals may have a thickness between the thickness of 1 atom (e.g., fraction of a nanometer, monolayer) to several micrometers (e.g., 1 to 10 micrometers).

Tetraethyl orthosilicate (TEOS) and fluorinated tetraethyl orthosilicate (FTEOS, fluorinated silicate glass) are dielectrics. TEOS and FTEOS may be used as inter-layer dielectrics. TEOS deposition and/or FTEOS deposition is a chemical vapor deposition (CVD) process that uses TEOS to grow silicon dioxide (SiO₂) films on silicon wafers. In the TEOS deposition process, TEOS is transported to the hot surface of the wafer via a carrier gas. The TEOS is then dissociated, and some of the decomposition products stick to the surface. The TEOS reacts with other species in the reactor to form a solid, high-quality SiO2 film. TEOS deposition is a complex pyrolytic chemical reaction. The process temperatures are usually not high enough to cause the diffusion of dopants in silicon. TEOS low pressure CVD (LPCVD) may be used to deposit oxide for dielectric materials, isolation layers, hard mask materials, and optical waveguides. High-k dielectric layers may be deposited using deposition processes such as physical vapor deposition (PVD), chemical vapor deposition (CVD), atomic layer deposition (ALD).

Silicon nitride is a material that may be used in semiconductor devices. Silicon nitride may be formed by reacting metallic silicon with gaseous nitrogen. The process may include reaction bonding, pressureless sintering, high nitrogen overpressure. Plasma enhanced chemical vapor deposition (PECVD) is a technique used to deposit thin-film layers of silicon nitride (SiN). PECVD reactors are also used to deposit aluminum oxide (Al₂O₃).

Photolithography is a manufacturing process for creating a patterned thin film of protective materials over a substrate, such as a silicon wafer, in order to protect selected areas during subsequent etching, deposition, and/or implantation operations. Optical lithography is a photon-based technique that uses light to produce patterned thin films on a substrate. Optical lithography, also known as photolithography or ultraviolet lithography, is a microfabrication process that involves selectively removing parts of a thin film before other processing actions (deposition or etching) are undertaken. In optical lithography, an image is projected onto a photosensitive emulsion (photoresist) coated onto a substrate, like a silicon wafer. The process uses ultraviolet or visible light and a photomask to print patterns onto the wafer's surface. Photomasking is a fabrication process that involves transferring a design to a thin layer of metal. The metal acts as an absorption layer for light at different wavelengths.

Etching is a process of microfabrication for removing layers from the surface of a wafer using chemical and/or physical means. With etching, part of the wafer may be protected from the etchant by a masking material that resists etching. In some cases, the masking material is a photoresist (PR) that has been patterned using photolithography.

A photoresist (also known as a resist) is a light-sensitive material used in several processes, such as photolithography and photoengraving, to form a patterned coating on a surface. This process is crucial in the electronics industry. The process may include coating a substrate with a light-sensitive organic material. A patterned mask is then applied to the surface to block light, so that only unmasked regions of the material are exposed to light. A solvent, called a developer, is then applied to the surface. In the case of a positive photoresist, the photo-sensitive material is degraded by light and the developer will dissolve away the regions that were exposed to light, leaving behind a coating where the mask was placed. In the case of a negative photoresist, the photosensitive material is strengthened (either polymerized or cross-linked) by light, and the developer will dissolve away only the regions that were not exposed to light, leaving behind a coating in areas where the mask was not placed.

Chemical mechanical polishing (CMP) is a fabrication technique that uses chemical oxidation and mechanical abrasion to remove material and achieve high levels of planarity. CMP is a manufacturing process to fabricate integrated circuits. CMP is used on a layer of the wafer to remove excess materials and create a smooth, planar surface. CMP may include a combination of chemical and mechanical (or abrasive) actions to achieve highly smooth and planar material surfaces.

Wet chemical processes are used in semiconductor manufacturing for etching, cleaning, and other stages. Wet cleaning is a process used in semiconductor fabrication that uses chemical solutions to remove dust, metal ions, contaminants, and organic impurities from the surface of wafers. Wet cleaning may use liquid chemical solvents and deionized water to oxidize, etch, and dissolve wafer surface contaminants, organic debris, and metal ion contamination.

Amorphous silicon (a-Si) is a non-crystalline form of silicon. In amorphous silicon, the silicon atoms are not arranged in crystal lattices, but in continuous disordered networks. Where crystalline silicon has atoms arranged in a highly ordered crystal lattice that extends in all directions, the atoms of amorphous silicon form a continuous random network. Amorphous silicon may be used in thin-film transistors and solar cells. Amorphous silicon can be vapor deposited onto substrates, making it useful for creating thin film transistors.

A MIM capacitor may include one or more metal (Mx) layers. The Mx layer may include one or more interconnects coupled to a voltage. In some cases, an Mx layer may be deposited on a barrier layer. A barrier layer prevents a metal layer (e.g., Cu) from diffusing into the dielectric layer at high temperatures. The function of a diffusion barrier layer is to prevent the active atomic diffusion of Cu towards dielectrics and Si. This prevents the structural breakdown of the Si/Cu junction and device degradation. The barrier layer is stable at high temperatures and adheres to both the Cu and the dielectric layer. In some examples, a barrier layer may be deposited on a dielectric layer (e.g., a substrate layer) and then Cu may be deposited on the dielectric layer. Tellurium (Te), Tantalum (Ta), or tantalum nitride (TaN) may be used as a barrier layer to separate a dielectric layer and Cu layer. In some cases, a diffusion barrier layer may include an intermediate layer or interlayer dielectric (ILD) layer that sits between two metals that acts as a barrier to protect the metals from corrupting each other. Examples of ILDs include silica (SiO2), hafnium silicate (HfSiO4), zirconium silicate (ZrSiO4), and carbon doped oxide thin film insulating material (SiCOH) that is composed of silicon (Si), carbon (C), oxygen (O), and hydrogen (H).

Field-effect transistors (FETs) are three-terminal devices that are commonly used for signal amplification. They are used in integrated circuits (ICs) due to their compact size and significantly lower power consumption. FETs use an electric field to control current flow, while metal-oxide-semiconductor field-effect transistors (MOSFETs) use an insulated gate. A junction field effect transistor (JFET) is a three-terminal semiconductor device that can be used as a switch, resistor, or amplifier. JFETs are unipolar current-controlled devices with three terminals: source, drain, and gate. With n-type semiconductors, the electrons have a negative charge, hence n-type. With p-type semiconductors, the effect of a positive charge is generated in the absence of an electron, hence p-type. An n-Channel semiconductor uses electron flow as the charge carrier, while p-Channel semiconductors use hole flow as the charge carrier, which has less mobility than electron flow. An n-channel FET (nFET), or n-type JFET, or n-channel MOSFET, is a voltage-controlled device that operates on the basis of a JFET. An nFET may be configured as a switch that is closed when the gate is given a 1 and open when the gate is given a 0. When an nFET receives a 1, it will pass a value through it. A p-channel FET (pFET), or p-type JFET, or p-channel MOSFET, is a type of transistor that acts as a switch. A pFET is closed when the gate is given a 0 and open when the gate is given a 1. Thus, pFETs are closed when the gate is given a 0 and open when the gate is given a 1, and nFETs are closed when the gate is given a 1 and open when the gate is given a 0. P-channel MOSFETs use a negative voltage from the gate to the source (VGS) to turn on, while N-channel MOSFETs use a positive VGS voltage to turn on.

The work function of a metal (WFM) is the minimum amount of energy needed to remove an electron from the metal. WFM is the energy difference between the vacuum level and the Fermi level. The work function is a constant for a metal, but it changes in a semiconductor depending on doping. The work function of a semiconductor is the Fermi level minus the vacuum level. The work function depends on the properties of the metal and the nature of its surface. For example, the work function tends to be smaller for metals with an open lattice, and larger for metals in which the atoms are closely packed. Different metals have different values of work function because of difference in their electronegativity behavior. The WFM gate can be an n-type WFM (nWFM) or a ptype WFM (pWFM). With the transition to high-k gate oxides, metal gate electrodes have been used to avoid the polysilicon depletion effect. The high-k metal gate process may have two types of gate electrode metal stacks (e.g., work function metals), one for the pFET (e.g., pWFM) and one for the nFET (e.g., nWFM). The work function metals are part of optimizing the nFET and pFET threshold voltage. The modulated threshold voltage (Vt) depends on the dipole formation of WFM atoms from the interface to dielectrics. The MIM structures described herein may include WFM deposition.

Atomic layer etching (ALE) is a technique that removes thin layers of material by alternating between chemical modification and etching steps. The chemical modification steps only affect the top atomic layers of the wafer, while the etching steps only remove the chemically-modified areas. In some cases, the MIM structure may be formed based on a high-throughput gas chemical etch ALE system (e.g., CERTAS®). In some cases, the MIM structure may be formed based on an ALE system for isotropic applications (e.g., SELECTRA®).

The average inversion-layer location (e.g., below the Si/SiO2 interface) may be referred to as the inversion-layer thickness (Tinv). The average gate leakage thickness (Toxgl) may be referred to as the silicon dioxide leakage equivalent thickness.

Pinch-off happens when a transistor turns off below a certain threshold voltage, which is known as the pinch-off voltage. Pinch-off occurs when the drain-source voltage (VDS) equals or exceeds the gate-source voltage minus the threshold voltage parameter (VGS-VT). The point where the inversion layer thickness is reduced to zero is called the pinch-off point.

MIM capacitors are important in modern electronic products, such as radio frequency (RF) products. Some MIM devices have some fundamental limitations based on a low capacitance density. Some MIM devices decrease high-k trade off with leakage and reliability. Some MIM devices have a relatively high series resistance in the bottom electrode.

The techniques described herein include multiple advantages and benefits that remedy the problems with some MIM devices. For example, the MIM structures described herein provides a high capacitance density with a relatively small area, relatively small space. The MIM structures described herein provides improved capacitance density and lower series resistance. The proposed process offers an additional advantage of saving a mask layer, which results in a significant reduction to cost.

MIM capacitors have been used for semiconductor devices related to analog-to-digital conversion and digital-to-analog conversion of apparatuses employing analog signals. Conversion between analog signals and digital signals requires capacitors and resistors. Also, as signals of which bits are numerous are used to increase the amount of data processed in data signals, semiconductor devices for processing signals should provide a reliable discrimination about shapes of signals. Also, the shapes of signals should not change with such variables as voltage and temperature. If capacitors of semiconductor devices have different capacitances according to voltage or temperature, it can become impossible to precisely determine and process signals.

Generally, formation of MIM capacitors can include forming a multiple layer structure of metal interconnections, which includes an upper interconnection, a via, and a lower interconnection, and forming lower and upper electrodes of the capacitor. The systems and methods described herein provide a MIM structure for improved capacitance density and lower series resistance. The proposed process offers advantages of saving a mask layer, resulting in a significant reduction to the cost of producing the MIM structure.

The techniques described herein provide a MIM capacitor device fabrication process resulting in an improved MIM capacitor structure. In some examples, the fabrication process may include stack deposition of one or more Mx layers and depositing thin-film layers (e.g., of silicon nitride (SiN)).

In some implementations, the fabrication process may include film stack deposition of multiple layers of metal (e.g., first metal) interspersed with layers of a semiconductor (e.g., amorphous silicon). In some cases, the fabrication process may include adding a photoresist for MIM area masking. In some examples, the fabrication process may include etching, where, based on the photoresist, rows of the multiple layers of metal interspersed with layers of semiconductor remain.

In some implementations, the fabrication process may include a TEOS deposition and chemical mechanical polishing (CMP). In some cases, the fabrication process may include adding a photoresist (e.g., a second photoresist). In some examples, the fabrication process may include etching, where, based on the photoresist, walls are formed around the MIM capacitor area based on the placement of the photoresist.

In some implementations, the fabrication process may include a wet chemical processes (e.g., wet clean). In some cases, the wet clean removes the amorphous silicon (a-Si) from the multiple layers of metal (e.g., first metal) of the MIM area. In some cases, the fabrication process may include atomic layer deposition (ALD).

In some examples, the fabrication process may include high-k dielectric deposition via ALD over exposed surfaces, including the MIM area. The high-k dielectric deposition results in the high-k dielectric filling in between the metal (e.g., first metal) in the spaces where the amorphous silicon had been interspersed between the metal (e.g., first metal).

In some implementations, the fabrication process may include a metal deposition (e.g., deposition of a second metal different from the first metal) and chemical mechanical polishing (CMP).

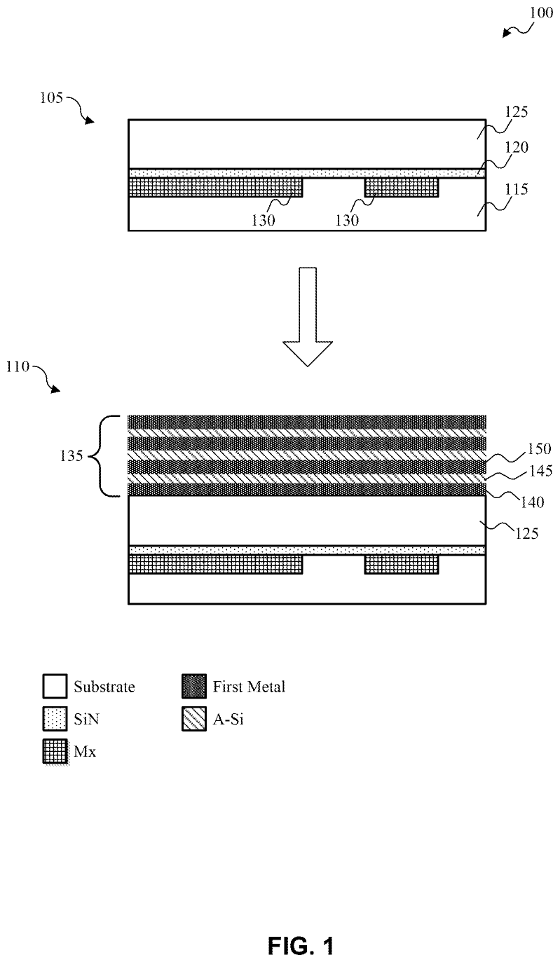

FIG. 1 illustrates a cross-sectional view illustrating an example of a semiconductor device 100 (e.g., MIM capacitor) in accordance with one or more implementations as described herein. FIG. 1 illustrates a semiconductor device fabrication process resulting in an improved MIM capacitor structure (e.g., increased capacitance density and lower series resistance compared to other methods and processes). The systems and methods described herein provide a MIM structure for improved capacitance density and lower series resistance. The proposed process offers advantages of saving a mask layer (e.g., reducing the number of mask layers), resulting in a significant reduction in the cost of producing the MIM structure.

At 105, semiconductor device 100 may be based on a semiconductor device fabrication process that includes forming base substrate layer 115, first dielectric layer 120 stacked on base substrate layer 115, and first substrate layer 125 stacked on first dielectric layer 120, base substrate layer 115 including at least one inter-layer metal segment 130 that spans a portion of and is adjacent to first dielectric layer 120. In some examples, the at least one inter-layer metal segment 130 (e.g., at least one Mx metal layer).

At 110, semiconductor device 100 may be based on a semiconductor device fabrication process that includes forming a metal-insulator-metal (MIM) capacitor area 135 on first substrate layer 125. In some examples, MIM capacitor area 135 may include at least first metal layer 140 (e.g., capacitor bottom metal (CBM) layer) of a first metal type. In some examples, MIM capacitor area 135 may include semiconductor layer 145 formed on first metal layer 140. In some examples, MIM capacitor area 135 may include second metal layer 150 (e.g., capacitor top metal (CTM) layer) of the first metal type (e.g., or of a second metal type different from the first metal type) formed on semiconductor layer 145.

In some implementations, first metal layer 140, semiconductor layer 145, and/or second metal layer 150 are formed via thin-film deposition (e.g., via film stack deposition). In some cases, semiconductor layer 145 includes amorphous silicon.

As shown, MIM capacitor area 135 may include multiple semiconductor layers that are sandwiched between a CBM layer and CTM layer. In the illustrated example, the semiconductor device fabrication process may include forming a first semiconductor layer (e.g., semiconductor layer 145) that includes a first CBM layer (e.g., first metal layer 140) and a first CTM layer (e.g., second metal layer 150).

As shown, the semiconductor device fabrication process of MIM capacitor area 135 includes forming a second semiconductor layer on the first CTM layer (e.g., second metal layer 150), where the second semiconductor layer is sandwiched between the first CTM layer (e.g., second metal layer 150 is also a second CBM layer with respect to the second semiconductor layer) and a second CTM layer on the second semiconductor layer.

As shown, the semiconductor device fabrication process of MIM capacitor area 135 includes forming a third semiconductor layer on the second CTM layer, where the third semiconductor layer is sandwiched between the second CTM layer (e.g., the second CTM layer is also a third CBM layer with respect to the third semiconductor layer) and a third CTM layer on the third semiconductor layer.

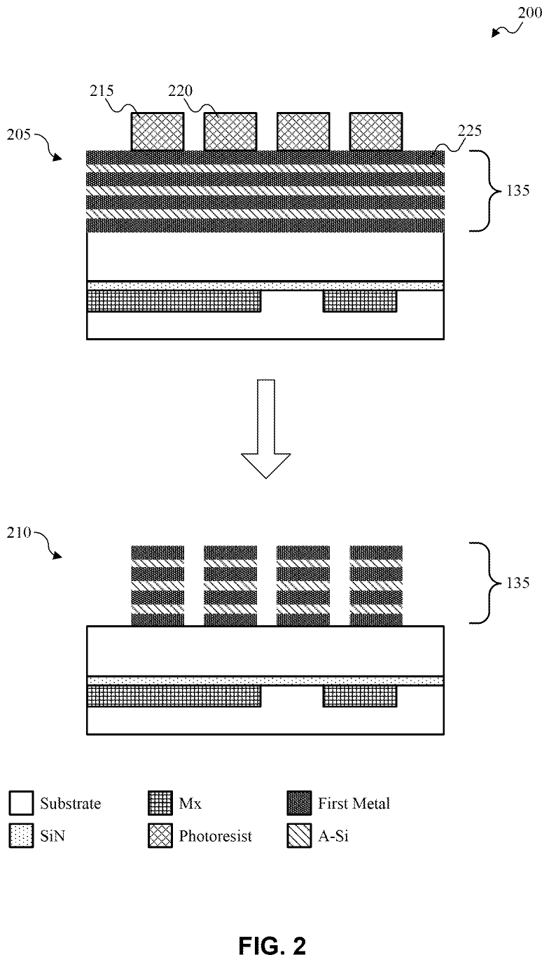

FIG. 2 illustrates a cross-sectional view illustrating an example of a semiconductor device 200 in accordance with one or more implementations as described herein. FIG. 2 illustrates a semiconductor device fabrication process resulting in an improved MIM capacitor structure. In the illustrated example, semiconductor device 200 may be based on semiconductor device 100 of FIG. 1.

At 205, semiconductor device 200 may be based on a semiconductor device fabrication process that includes applying multiple photoresists (e.g., at least a first photoresist 215 and a second photoresist 220) to top metal layer 225 of MIM capacitor area 135. As shown, the first photoresist 215 spans a first portion of top metal layer 225 and second photoresist 220 spans a second portion of top metal layer 225 different from the first portion. In some cases, the semiconductor device fabrication process includes applying more than two photoresists (e.g., four rows of photoresist on top metal layer 225 in the illustrated example).

At 210, the semiconductor device fabrication process may include forming rows of MIM capacitor area 135 (e.g., rows of stacked metal layers) based on etching exposed portions of MIM capacitor area 135 between the multiple photoresists (e.g., exposed portions on either side of at least the first photoresist 215 and the second photoresist 220). As shown, several rows of MIM capacitor area 135 remain after etching.

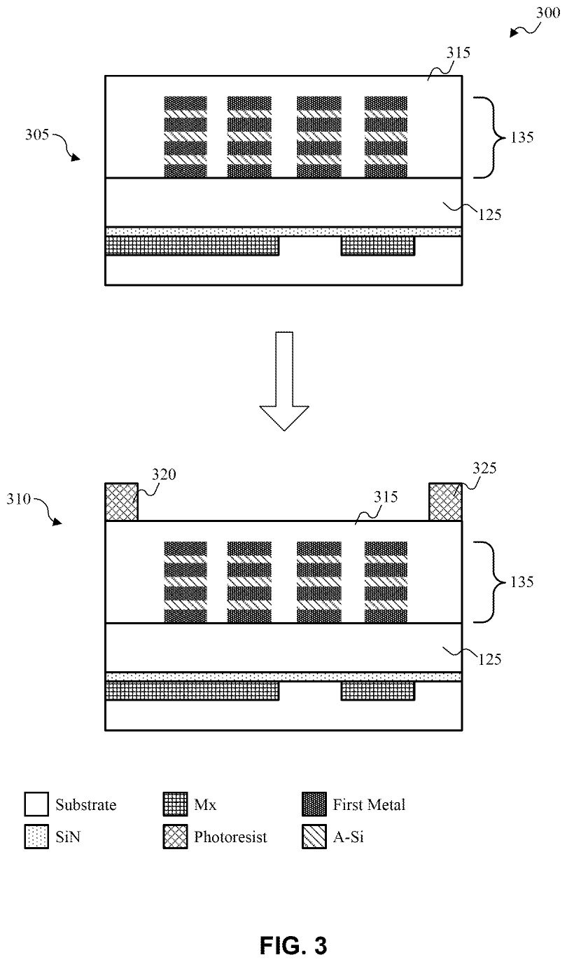

FIG. 3 illustrates a cross-sectional view illustrating an example of a semiconductor device 300 in accordance with one or more implementations as described herein. FIG. 3 illustrates a semiconductor device fabrication process resulting in an improved MIM capacitor structure. In the illustrated example, semiconductor device 300 may be based on semiconductor device 200 of FIG. 2.

At 305, semiconductor device 300 may be based on a semiconductor device fabrication process that includes depositing a second substrate layer 315 over the rows of MIM capacitor area 135. As shown, second substrate layer 315 is deposited over first substrate layer 125 and MIM capacitor area 135. As shown, second substrate layer 315 covers, envelopes, and/or encapsulates the rows of MIM capacitor area 135. In some cases, the semiconductor device fabrication process includes forming a planar surface over second substrate layer 315 based on chemical mechanical polishing.

At 310, semiconductor device 300 may be based on a semiconductor device fabrication process that includes applying a third photoresist 320 and a fourth photoresist 325 on second substrate layer 315. In some examples, third photoresist 320 may be applied adjacent to a first edge (e.g., left outer edge of the illustrated example) of second substrate layer 315 and fourth photoresist 325 may be applied adjacent a second edge (e.g., right edge of the illustrated example) of second substrate layer 315. In some cases, third photoresist 320 and fourth photoresist 325 may be part of a photoresist placed around a border of semiconductor device 300. For example, semiconductor device 300 may be formed generally in a cubical formation. For instance, the photoresist placed on the top surface of semiconductor device 300, running around an outer edge of a top surface of semiconductor device 300 (e.g., along each of four edges of a square-shaped top surface of semiconductor device 300), where third photoresist 320 and fourth photoresist 325 are cross-sections of the photoresist (e.g., on two of four outer edges of the top surface of semiconductor device 300).

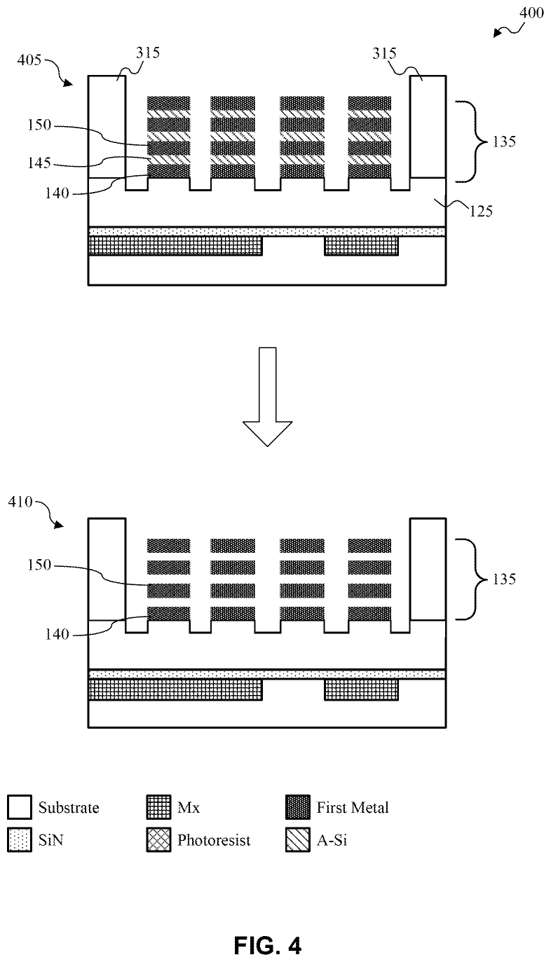

FIG. 4 illustrates a cross-sectional view illustrating an example of a semiconductor device 400 in accordance with one or more implementations as described herein. FIG. 4 illustrates a semiconductor device fabrication process resulting in an improved MIM capacitor structure. In the illustrated example, semiconductor device 400 may be based on semiconductor device 300 of FIG. 3.

At 405, semiconductor device 400 may be based on a semiconductor device fabrication process that includes exposing the rows of MIM capacitor area 135 based on etching portions of second substrate layer 315 between the rows and portions of first substrate layer 125 between the rows. It is noted that third photoresist 320 are fourth photoresist 325 are removed as part of the etching process. As shown, outer portions (e.g., outer edge portions) of second substrate layer 315 remain based on the placement of third photoresist 320 and fourth photoresist 325.

At 410, the semiconductor device fabrication process may include removing the semiconductor layers of MIM capacitor area 135 (e.g., semiconductor layer 145) between the metal layers of MIM capacitor area 135 (e.g., first metal layer 140, second metal layer 150, etc.) based on applying a wet clean solution to the rows of MIM capacitor area 135. In some examples, the wet clean solution forms a cavity around MIM capacitor area 135, where second substrate layer 315 forms sidewalls of the cavity and the rows of MIM capacitor area 135 are within the cavity. In some cases, the removal of semiconductor layers (e.g., layers of amorphous silicon) is based on a reactive clean process.

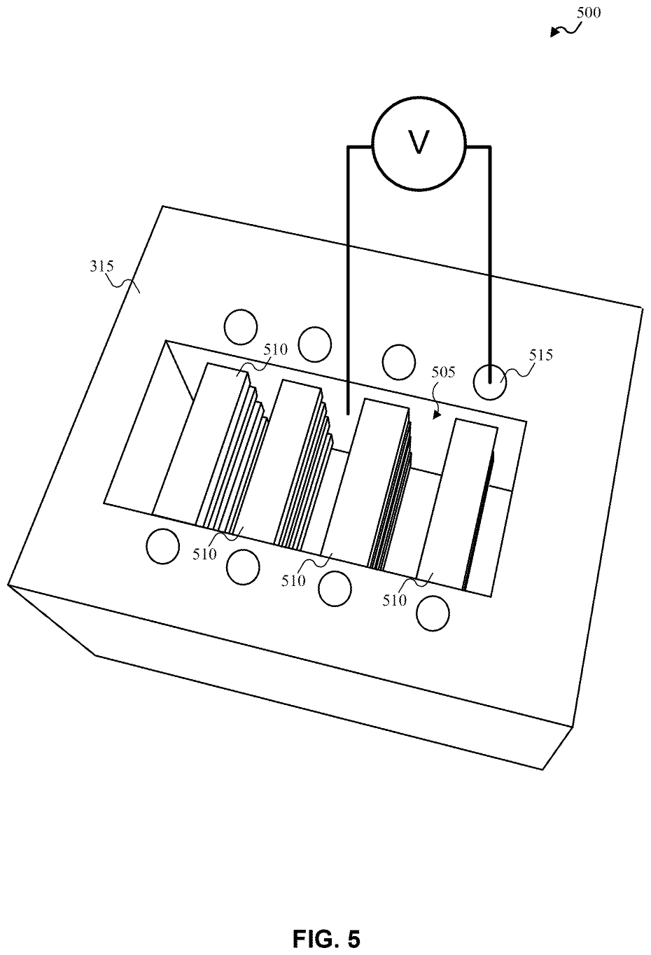

FIG. 5 illustrates a three-dimensional top-down view illustrating an example of a semiconductor device 500 in accordance with one or more implementations as described herein. FIG. 5 illustrates a semiconductor device fabrication process resulting in an improved MIM capacitor structure. In the illustrated example, semiconductor device 500 may be based on semiconductor device 400 of FIG. 4.

As shown, semiconductor device 500 depicts a top surface of second substrate layer 315 and the outer edges or outer sidewalls of second substrate layer 315. In the illustrated example, semiconductor device 500 depicts a cavity 505 of second substrate layer 315 and inner edges or inner sidewalls of second substrate layer 315. As shown, semiconductor device 500 depicts rows 510 of MIM capacitor area 135. In the illustrated example, semiconductor device 500 depicts at least one metal pad 515 (e.g., at least one copper pad) of the semiconductor device 500 (e.g., a MIM capacitor).

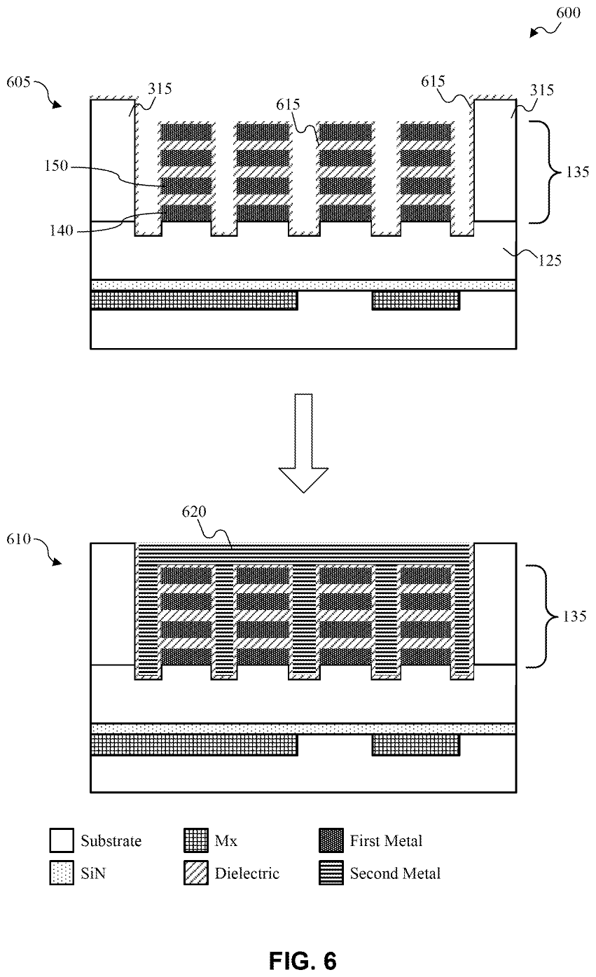

FIG. 6 illustrates a cross-sectional view illustrating an example of a semiconductor device 600 in accordance with one or more implementations as described herein. FIG. 6 illustrates a semiconductor device fabrication process resulting in an improved MIM capacitor structure. In the illustrated example, semiconductor device 600 may be based on semiconductor device 400 of FIG. 4 and/or semiconductor device 500 of FIG. 5.

At 605, semiconductor device 600 may be based on a semiconductor device fabrication process that includes depositing a second dielectric 615 over the rows of MIM capacitor area 135 and between the metal layers of MIM capacitor area 135 (e.g., first metal layer 140, second metal layer 150, etc.), over surfaces of first substrate layer 125 between the rows, over surfaces of the inner sidewalls of second substrate layer 315, and/or over a top surface of second substrate layer 315. In some examples, second dielectric 615 is deposited based on atomic layer deposition.

At 610, the semiconductor device fabrication process may include depositing a second metal 620 over and between the rows of MIM capacitor area 135 (e.g., over second dielectric 615).

In some implementations, second metal 620 is a second type of metal that is different from a first metal type of the metal layers of MIM capacitor area 135 (e.g., first metal layer 140, second metal layer 150, etc.). In some examples, second metal 620 is a same type of metal used for the metal layers of MIM capacitor area 135 (e.g., first metal layer 140, second metal layer 150, etc.).

As shown, second metal 620 covers the rows of MIM capacitor area 135 and second dielectric 615 and fills in space between the rows. In some cases, the semiconductor device fabrication process may include forming a planar surface over second metal 620 based on chemical mechanical polishing.

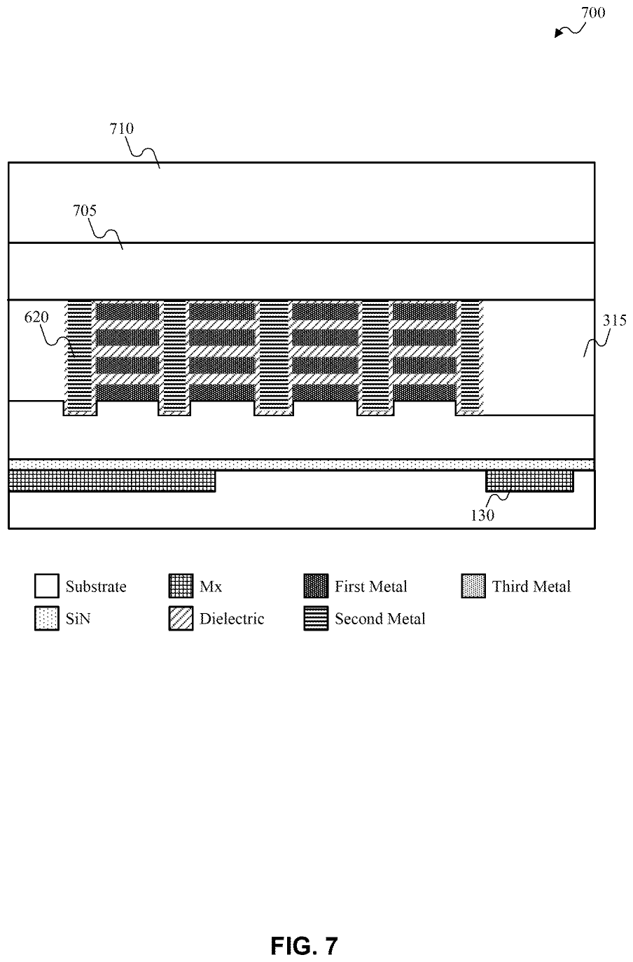

FIG. 7 illustrates a cross-sectional view illustrating an example of a semiconductor device 700 in accordance with one or more implementations as described herein. FIG. 7 illustrates a semiconductor device fabrication process resulting in an improved MIM capacitor structure with increased capacitance density and lower series resistance compared to other methods and processes. In some examples, the fabrication process may include TEOS deposition, FTEOS deposition, and/or ion beam (IB) deposition. In the illustrated example, semiconductor device 700 may be based on semiconductor device 600 of FIG. 6.

In the illustrated example, semiconductor device fabrication process of semiconductor device 700 may include using TEOS deposition to form TEOS layer 705. As shown, TEOS layer 705 is deposited over second metal 620 and over MIM capacitor area 135.

As shown, semiconductor device fabrication process of semiconductor device 700 may include using FTEOS deposition to form FTEOS layer 710. As shown, FTEOS layer 710 is deposited over TEOS layer 705.

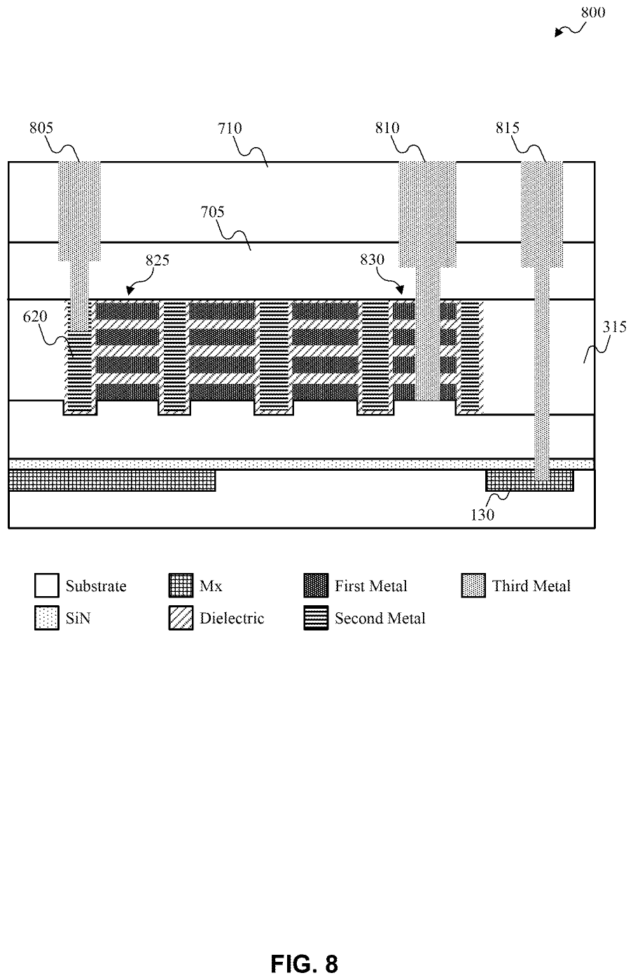

FIG. 8 illustrates a cross-sectional view illustrating an example of a semiconductor device 800 in accordance with one or more implementations as described herein. FIG. 8 illustrates a semiconductor device fabrication process resulting in an improved MIM capacitor structure with increased capacitance density and lower series resistance compared to other methods and processes. In some examples, the fabrication process may include an 8× metal and via process. In the illustrated example, semiconductor device 800 may be based on semiconductor device 700 of FIG. 7.

In the illustrated example, semiconductor device 800 may be based on a semiconductor device fabrication process that includes via 805, via 810, and/or via 815. As shown, via 805 may pass through FTEOS layer 710, TEOS layer 705, and connects to at least one portion of second metal 620. As shown, via 805 may connect to a portion of second metal 620 that is located between an outer sidewall of second substrate layer 315 and a first row 825 of the stack of metal layers of MIM capacitor area 135 (e.g., left outer row of MIM capacitor area 135 in the illustrated example).

In the illustrated example, via 810 may pass through FTEOS layer 710, TEOS layer 705, and connect to a last row 830 of the stack of metal layers of MIM capacitor area 135 (e.g., right outer row of MIM capacitor area 135 in the illustrated example). In the illustrated example, via 815 may pass through FTEOS layer 710, TEOS layer 705, and connect to inter-layer metal segment 130.

It is noted that at 610 of FIG. 6, second metal 620 covers the rows of MIM capacitor area 135 where second metal 620 exceeds a height of the rows of MIM capacitor area 135. As shown in FIG. 8 (or FIG. 7), the height of second metal 620 is reduced to near the height of a top layer of the rows of MIM capacitor area 135. For example, the height of second metal 620 may be relatively near or even with the height of a top layer of the rows of MIM capacitor area 135 (e.g., 0 to 10 nm above). Thus, in some examples, the height of second metal 620 may be reduced (e.g., via CMP) to be relatively near or at the height of a top layer of the rows of MIM capacitor area 135 (e.g., relatively near or at the height of the top of the second dielectric 615 deposited over the rows of MIM capacitor area 135 as shown in FIG. 6). Alternatively, the height of second metal 620 may be maintained to be above the height of a top layer of the rows of MIM capacitor area 135 (e.g., as in FIG. 6 at 610). For example, TEOS layer 705 and FTEOS layer 710 may be deposited over second metal 620, where the height of second metal 620 is maintained above the height of a top layer of the rows of MIM capacitor area 135 (e.g., 1 nm to 1 mm above the height of a top layer of the rows of MIM capacitor area 135).

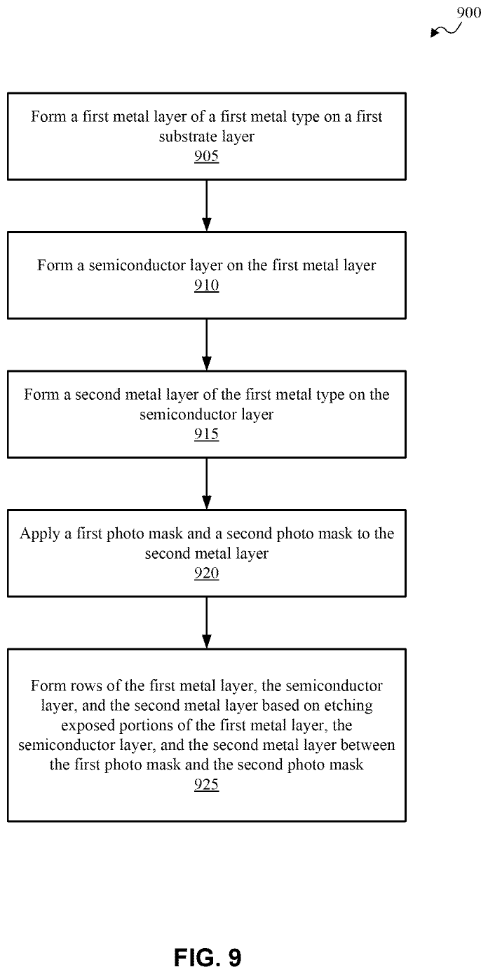

FIG. 9 depicts a flow diagram illustrating an example method 900 associated with the disclosed systems, in accordance with example implementations described herein. In some configurations, the method 900 may be implemented by one or more semiconductor fabrication devices. The method 900 is just one implementation and one or more operations of the method 900 may be rearranged, reordered, omitted, and/or otherwise modified such that other implementations are possible and contemplated. The techniques described herein include logic to provide multilayer metal-insulator-metal capacitors for increased capacitance density. The logic includes any combination of hardware (e.g., at least one memory, at least one processor), logical circuitry, firmware, and/or software to provide multilayer metal-insulator-metal capacitors for increased capacitance density.

At 905, the method 900 may include forming a first metal layer of a first metal type on a first substrate layer. For example, a thin-film metallic layer may be formed on the first substrate layer.

At 910, the method 900 may include forming a semiconductor layer on the first metal layer. In some examples, the semiconductor layer includes amorphous silicon.

At 915, the method 900 may include forming a second metal layer of the first metal type on the semiconductor layer. In some examples, the first metal layer, the semiconductor layer, and/or the second metal layer are formed via thin-film deposition.

At 920, the method 900 may include applying a first photoresist and a second photoresist to the second metal layer. In some examples, the first photoresist spans a first portion of the second metal layer and the second photoresist spans a second portion of the second metal layer different from the first portion.

At 925, the method 900 may include forming rows of the first metal layer, the semiconductor layer, and the second metal layer based on etching exposed portions of the first metal layer, the semiconductor layer, and the second metal layer between the first photoresist and the second photoresist. In some examples, the rows include a metal-insulator-metal (MIM) capacitor area of the semiconductor device.

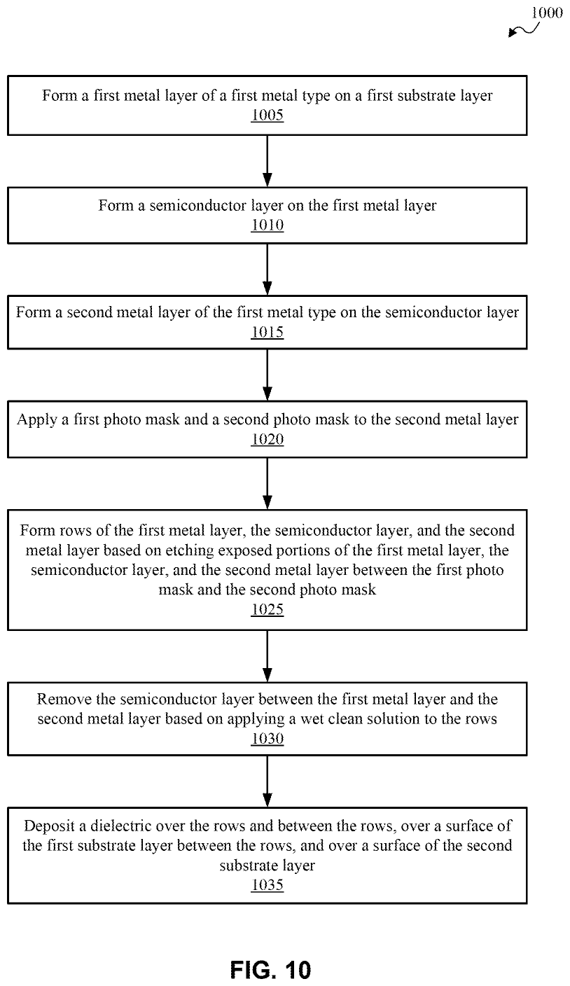

FIG. 10 depicts a flow diagram illustrating an example method 1000 associated with the disclosed systems, in accordance with example implementations described herein. In some configurations, the method 1000 may be implemented by one or more semiconductor fabrication devices. The method 1000 is just one implementation and one or more operations of the method 1000 may be rearranged, reordered, omitted, and/or otherwise modified such that other implementations are possible and contemplated. The techniques described herein include logic to provide multilayer metal-insulator-metal capacitors for increased capacitance density. The logic includes any combination of hardware (e.g., at least one memory, at least one processor), logical circuitry, firmware, and/or software to provide multilayer metal-insulator-metal capacitors for increased capacitance density.

At 1005, the method 1000 may include forming a first metal layer of a first metal type on a first substrate layer. For example, a thin-film metallic layer may be formed on the first substrate layer.

At 1010, the method 1000 may include forming a semiconductor layer on the first metal layer. In some examples, the semiconductor layer includes amorphous silicon.

At 1015, the method 1000 may include forming a second metal layer of the first metal type on the semiconductor layer. In some examples, the first metal layer, the semiconductor layer, and/or the second metal layer are formed via thin-film deposition.

At 1020, the method 1000 may include applying a first photoresist and a second photoresist to the second metal layer. In some examples, the first photoresist spans a first portion of the second metal layer and the second photoresist spans a second portion of the second metal layer different from the first portion.

At 1025, the method 1000 may include forming rows of the first metal layer, the semiconductor layer, and the second metal layer based on etching exposed portions of the first metal layer, the semiconductor layer, and the second metal layer between the first photoresist and the second photoresist. In some examples, the rows include a metal-insulator-metal (MIM) capacitor area of the semiconductor device.

At 1030, the method 1000 may include removing the semiconductor layer between the first metal layer and the second metal layer based on applying a wet clean solution to the rows.

At 1035, the method 1000 may include depositing a dielectric over the rows and between the rows, over a surface of the first substrate layer between the rows, and over a surface of the second substrate layer.

The MIM structures described herein provide an increased capacitance density with a relatively small area and relatively small space compared to other MIM structures. Also, the MIM structures described herein provide lower series resistance. Additionally, the described techniques provide methods and processes for forming multilayer MIM capacitors with increased capacitance density and lower series resistance compared to other methods and processes. Furthermore, the proposed process offers additional advantage of saving a mask layer (e.g., using at least one less mask layer than other processes), which results in a significant reduction to the cost of manufacturing.

In the examples described herein, the configurations and operations are example configurations and operations, and may involve various additional configurations and operations not explicitly illustrated. In some examples, one or more aspects of the illustrated configurations and/or operations may be omitted. In some embodiments, one or more of the operations may be performed by components other than those illustrated herein. Additionally, or alternatively, the sequential and/or temporal order of the operations may be varied.

Certain embodiments may be implemented in one or a combination of hardware, firmware, and software. Other embodiments may be implemented as instructions stored on a computer-readable storage device, which may be read and executed by at least one processor to perform the operations described herein.

The word “exemplary” is used herein to mean “serving as an example, instance, or illustration.” Any embodiment described herein as “exemplary” is not necessarily to be construed as preferred or advantageous over other embodiments.

Although an example processing system has been described above, embodiments of the subject matter and the functional operations described herein can be implemented in other types of semiconductor devices and/or other semiconductor fabrication processes, including the structures disclosed in this specification and their structural equivalents, or in combinations of one or more of them.

The operations described herein can be implemented as operations performed by a semiconductor fabrication apparatus on information/instructions stored on one or more computer-readable storage devices or received from other sources.

Reference to semiconductor devices, fabrication thereof, and/or machines that perform the fabrication thereof encompasses all types of apparatus, devices, and machines for fabricating semiconductor devices, including by way of example a programmable processor, a computer, a system on a chip, or multiple ones, or combinations, of the foregoing. The apparatus can include special purpose logic circuitry, for example an FPGA (field programmable gate array) or an ASIC (application-specific integrated circuit). The apparatus can also include, in addition to hardware, code that creates an execution environment for the computer program in question, for example code that constitutes processor firmware, a protocol stack, a database management system, an operating system, a cross-platform runtime environment, a virtual machine, or a combination of one or more of them, associated with semiconductor fabrication.

Semiconductor fabrication may be based on one or more computer programs stored in memory and/or executed by one or more processors. A computer program (also known as a program, software, software application, script, or code) can be written in any form of programming language, including compiled or interpreted languages, declarative or procedural languages, and it can be deployed in any form, including as a stand-alone program or as a component, component, subroutine, object, or other unit suitable for use in a computing environment. A computer program may, but need not, correspond to a file in a file system. A program can be stored in a portion of a file that holds other programs or information/data (for example one or more scripts stored in a markup language document), in a single file dedicated to the program in question, or in multiple coordinated files (for example files that store one or more components, sub-programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, for example magnetic, magneto-optical disks, or optical disks. However, a computer need not have such devices. Devices suitable for storing computer program instructions and information/data include all forms of non-volatile memory, media and memory devices, including by way of example semiconductor memory devices, for example EPROM, EEPROM, and flash memory devices; magnetic disks, for example internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, for example a CRT (cathode ray tube) or LCD (liquid crystal display) monitor, for displaying information/data to the user and a keyboard and a pointing device, for example a mouse or a trackball, by which the user can provide input to the computer. Other kinds of devices can be used to provide for interaction with a user as well; for example, feedback provided to the user can be any form of sensory feedback, for example visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, for example as an information/data server, or that includes a middleware component, for example an application server, or that includes a front-end component, for example a client computer having a graphical user interface or a web browser through which a user can interact with an embodiment of the subject matter described herein, or any combination of one or more such back-end, middleware, or front-end components. The components of the system can be interconnected by any form or medium of digital information/data communication, for example a communication network. Examples of communication networks include a local area network (“LAN”) and a wide area network (“WAN”), an inter-network (for example the Internet), and peer-to-peer networks (for example ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (for example an HTML page) to a client device (for example for purposes of displaying information/data to and receiving user input from a user interacting with the client device). Information/data generated at the client device (for example a result of the user interaction) can be received from the client device at the server.

While this specification contains many specific embodiment details, these should not be construed as limitations on the scope of any embodiment or of what may be claimed, but rather as descriptions of features specific to particular embodiments. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain embodiments, multitasking and parallel processing may be advantageous.

Many modifications and other examples described herein set forth herein will come to mind to one skilled in the art to which these embodiments pertain having the benefit of the teachings presented in the foregoing descriptions and the associated drawings. Therefore, it is to be understood that the embodiments are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed:

1. A method of fabricating a semiconductor device, comprising:
forming a first metal layer of a first metal type on a first substrate layer;
forming a semiconductor layer on the first metal layer;
forming a second metal layer of the first metal type on the semiconductor layer;
applying a first photoresist and a second photoresist to the second metal layer, wherein the first photoresist spans a first portion of the second metal layer and the second photoresist spans a second portion of the second metal layer different from the first portion; and
forming rows of the first metal layer, the semiconductor layer, and the second metal layer based on etching exposed portions of the first metal layer, the semiconductor layer, and the second metal layer between the first photoresist and the second photoresist.

2. The method of claim 1, wherein the rows comprise a metal-insulator-metal (MIM) capacitor area of the semiconductor device.

3. The method of claim 1, wherein:
the semiconductor layer includes amorphous silicon, and
the first metal layer, the semiconductor layer, and the second metal layer are formed via thin-film deposition.

4. The method of claim 1, further comprising depositing a second substrate layer over the rows, wherein the second substrate layer encapsulates the rows.

5. The method of claim 4, further comprising forming a planar surface over the second substrate layer based on chemical mechanical polishing.

6. The method of claim 4, further comprising applying a third photoresist and a fourth photoresist on the second substrate layer.

7. The method of claim 6, further comprising exposing the rows based on etching the third photoresist, the fourth photoresist, portions of the second substrate layer between the rows, and portions of the first substrate layer between the rows.

8. The method of claim 6, wherein the third photoresist is applied adjacent to a first edge of the second substrate layer and the fourth photoresist is applied adjacent a second edge of the second substrate layer.

9. The method of claim 8, wherein a first sidewall of the second substrate layer remains based on the third photoresist and a second sidewall of the second substrate layer remains based on the fourth photoresist, the first sidewall including the first edge and the second sidewall including the second edge of the second substrate layer.

10. The method of claim 8, further comprising removing the semiconductor layer between the first metal layer and the second metal layer based on applying a wet clean solution to the rows.

11. The method of claim 10, wherein the wet clean solution forms a cavity, the second substrate layer forming sidewalls of the cavity and the rows being within the cavity.

12. The method of claim 10, further comprising depositing a dielectric layer over the rows and between the rows, over a surface of the first substrate layer between the rows, and over a surface of the second substrate layer.

13. The method of claim 12, wherein the dielectric layer is deposited based on atomic layer deposition.

14. The method of claim 12, further comprising depositing a second metal type over and between the rows, wherein the second metal type covers the rows and the dielectric layer and fills in space between the rows.

15. The method of claim 14, further comprising forming a planar surface over the second metal type based on chemical mechanical polishing.

16. A semiconductor device, comprising:
a first metal layer of a first metal type formed on a first substrate layer;
a semiconductor layer formed on the first metal layer via film stack deposition;
a second metal layer of the first metal type formed on the semiconductor layer; and
a first photoresist and a second photoresist applied to the second metal layer, wherein:
the first metal layer, the semiconductor layer, and the second metal layer are formed via thin-film deposition,
the first photoresist spans a first portion of the second metal layer and the second photoresist spans a second portion of the second metal layer different from the first portion, and
rows of the first metal layer, the semiconductor layer, and the second metal layer are formed based on an etching of exposed portions of the first metal layer, the semiconductor layer, and the second metal layer between the first photoresist and the second photoresist.

17. The semiconductor device of claim 16, wherein:
the rows comprise a metal-insulator-metal (MIM) capacitor area of the semiconductor device, and
the semiconductor layer includes amorphous silicon.

18. The semiconductor device of claim 16, further comprising:
a second substrate layer deposited over the rows, wherein the second substrate layer encapsulates the rows; and
a planar surface formed over the second substrate layer based on chemical mechanical polishing.

19. The semiconductor device of claim 18, further comprising a third photoresist and a fourth photoresist applied on the second substrate layer, wherein the third photoresist is applied adjacent to a first edge of the second substrate layer and the fourth photoresist is applied adjacent a second edge of the second substrate layer.

20. The semiconductor device of claim 19, further comprising exposing the rows based on etching the third photoresist, the fourth photoresist, portions of the second substrate layer between the rows, and portions of the first substrate layer between the rows, wherein a first sidewall of the second substrate layer remains based on the third photoresist and a second sidewall of the second substrate layer remains the fourth photoresist, the first sidewall including the first edge and the second sidewall including the second edge of the second substrate layer.
